(19) United States
(12) Patent Application Publication
(10) Pub. No.: US 2026/0349269 A1
(43) Pub. Date: Nov. 5, 2026

(54) Systems, Methods, And Devices For Anamorphic Optics In Lithography

(71) Applicant: EUV Tech, Inc., Martinez, CA (US)

(72) Inventor: Patrick Naulleau, Pleasant Hill, CA (US)

(21) Appl. No.: 19/195,106

(22) Filed: Apr. 30, 2025

(51) Int. Cl. G02B 27/42; G02B 5/18; G03F 7/00

(52) U.S. Cl. CPC G02B 27/4222; G02B 5/1876; G02B 27/4277; G03F 7/70033; G03F 7/70108; G03F 7/70158; G03F 7/702; G03F 7/70316

(57) ABSTRACT

Systems, methods, and devices disclosed herein perform anamorphic imaging of lithography targets in various operational environments. Systems include a focusing device configured to receive an optical input, the focusing device including a first diffractive optic configured to receive an optical input based on light generated by the light source, and further configured to generate a first optical output having first magnification parameters along a first direction of an optical plane. The focusing device also includes a second diffractive optic configured to receive the first optical output, and further configured to generate a second optical output having second magnification parameters along a second direction of the optical plane. The first direction is different than the second direction, and the second optical output has a uniform depth of focus along the first direction and the second direction. Systems also include an imaging device configured to receive the second optical output.

### FIELD OF TECHNOLOGY

This patent application relates generally to metrology, microscopy, and inspection in support of lithography, and more specifically to anamorphic imaging for extreme ultraviolet (EUV) microscopy of lithographic photomasks.

### BACKGROUND

Lithography techniques may use one or more patterning techniques to apply a pattern to a lithography target. For example, photolithography may use light to induce changes in the lithography target that may subsequently be used to etch a pattern in the lithography target. The pattern itself may be represented in a photomask which may be used in combination with a resist that coats the lithography target itself. Imaging optics may be used to obtain images of the mask and evaluate properties of the mask layer. Such evaluation is performed because any relevant error on the mask will be replicated into every computer chip manufactured through the lithography process. Conventional techniques for obtaining such images remain limited because they are not able to efficiently provide a uniform depth of focus for imaging of such photomasks while also emulating optical properties of lithography operations at the underlying wafer.

### SUMMARY

In some embodiments, techniques described herein relate to a system for anamorphic imaging for lithography. In some embodiments, the features described herein relate to a system including: a focusing device configured to receive an optical input based on light generated by a light source, the focusing device including: a first diffractive optic configured to receive an optical input based on light generated by a light source, and further configured to generate a first optical output having first magnification parameters along a first direction of an optical plane; and a second diffractive optic configured to receive the first optical output, and further configured to generate a second optical output having second magnification parameters along a second direction of the optical plane, wherein the first direction is different than the second direction, and wherein the second optical output has a uniform depth of focus along the first direction and the second direction associated with an imaging plane; an imaging device configured to receive the second optical output at the imaging plane.

In some embodiments, the features described herein relate to a system, wherein the first diffractive optic includes a first cylindrical zone plate, and wherein the second diffractive optic includes a second cylindrical zone plate. In some embodiments, the features described herein relate to a system, wherein the first diffractive optic and the second diffractive optic are configured to be adjustably positioned along an optical axis. In some embodiments, the features described herein relate to a system further including: a third diffractive optic configured to generate a third optical output having third magnification parameters.

In some embodiments, the features described herein relate to a system, wherein the third diffractive optic is positioned after an intermediate image generated by the second diffractive optic. In some embodiments, the features described herein relate to a system, wherein the third diffractive optic is a zone plate lens configured to provide magnification in both the first direction and the second direction. In some embodiments, the features described herein relate to a system further including: a mirror configured to generate a third optical output having third magnification parameters. In some embodiments, the features described herein relate to a system further including: a scintillator configured to convert extreme ultraviolet (EUV) light included in the second optical output to visible light; and an optic configured to generate a third optical output having third magnification parameters. In some embodiments, the features described herein relate to a system, wherein the optical input is received based on light from the light source reflecting off of a lithography target. In some embodiments, the features described herein relate to a system, wherein the light source is an EUV light source.

In some embodiments, the features described herein relate to a device including: a first diffractive optic configured to receive an optical input based on light generated by a light source, and further configured to generate a first optical output having first magnification parameters along a first direction of an optical plane; and a second diffractive optic configured to receive the first optical output, and further configured to generate a second optical output having second magnification parameters along a second direction of the optical plane, wherein the first direction is different than the second direction, and wherein the second optical output has a uniform depth of focus along the first direction and the second direction associated with an imaging plane.

In some embodiments, the features described herein relate to a device, wherein the first diffractive optic includes a first cylindrical zone plate, and wherein the second diffractive optic includes a second cylindrical zone plate. In some embodiments, the features described herein relate to a device, wherein the first diffractive optic and the second diffractive optic are configured to be adjustably positioned along an optical axis. In some embodiments, the features described herein relate to a device, wherein the first direction is orthogonal to the second direction. In some embodiments, the features described herein relate to a device further including: a third diffractive optic configured to generate a third optical output having third magnification parameters.

In some embodiments, the features described herein relate to a device, wherein the third diffractive optic is a zone plate lens configured to provide magnification in both the first direction and the second direction. In some embodiments, the features described herein relate to a device further including: one or more mirrors configured to configured to generate a third optical output having third magnification parameters. In some embodiments, the features described herein relate to a device further including: a scintillator configured to convert extreme ultraviolet light included in the second optical output to visible light; and an optic configured to generate a third optical output having third magnification parameters.

In some embodiments, the features described herein relate to a method including: receiving an optical input based on light generated by a light source; generating, using a first diffractive optic, a first optical output having first magnification parameters along a first direction of an optical plane; and generating, using a second diffractive optic, a second optical output having second magnification parameters along a second direction of the optical plane, wherein the first direction is different than the second direction, and wherein the second optical output has a uniform depth of focus along the first direction and the second direction associated with an imaging plane.

In some embodiments, the features described herein relate to a method, wherein the first diffractive optic includes a first cylindrical zone plate, and wherein the second diffractive optic includes a second cylindrical zone plate. In some embodiments, the features described herein relate to a method further including: generating, using a third diffractive optic, a third optical output having third magnification parameters, wherein the third diffractive optic is positioned after an intermediate image generated by the second diffractive optic. In some embodiments, the features described herein relate to a method, wherein the third diffractive optic is a zone plate lens configured to provide magnification in both the first direction and the second direction.

In some embodiments, the features described herein relate to a method further including: generating, using a mirror, a third optical output having third magnification parameters. In some embodiments, the features described herein relate to a method further including: converting, using a scintillator, extreme ultraviolet (EUV) light included in the second optical output to visible light; and generating, using an optic, a third optical output having third magnification parameters. These and other embodiments are described further below with reference to the figures.

### BRIEF DESCRIPTION OF THE DRAWINGS

The included drawings are for illustrative purposes and serve only to provide examples of possible structures and operations for the disclosed inventive systems, apparatus, methods, and devices for anamorphic imaging of lithography photomasks. These drawings in no way limit any changes in form and detail that may be made by one skilled in the art without departing from the spirit and scope of the disclosed implementations.

FIG. 1 illustrates an example of a system for anamorphic imaging, configured in accordance with some embodiments.

FIG. 2 illustrates an example of a device for anamorphic imaging, configured in accordance with some embodiments.

FIG. 3 illustrates another example of a device for anamorphic imaging, configured in accordance with some embodiments.

FIG. 4 illustrates an additional example of a device for anamorphic imaging, configured in accordance with some embodiments.

FIG. 5 illustrates another example of a device for anamorphic imaging, configured in accordance with some embodiments.

FIG. 6 illustrates an example of a method for anamorphic imaging, performed in accordance with some embodiments.

FIG. 7 illustrates another example of a method for anamorphic imaging, performed in accordance with some embodiments.

FIG. 8 illustrates an example of a method for anamorphic imaging, performed in accordance with some embodiments

FIG. 9 illustrates an additional example of a method for anamorphic imaging, performed in accordance with some embodiments.

FIG. 10 illustrates another example of a method for anamorphic imaging, performed in accordance with some embodiments.

### DETAILED DESCRIPTION

In various embodiments, resist layers and photomasks may be used during lithography operations applied to lithography targets, such as silicon wafers. In projection lithography operations, a lithography optic is used to project an image of the photomask to the lithography target, thereby replicating the circuit patterned onto the mask. Moreover, illumination and imaging techniques may be used for inspecting such photomasks used in lithography operations to ensure that the photomask is free of errors. When evaluating such photomask properties, the imaging properties of the lithography tool are emulated, and such emulated imaging properties may include the through focus characteristics of the lithography tool.

In various embodiments, the lithography tool may use different depths of focus in different directions of the photomask and associated wafer plane as EUV light may be provided to a downstream target via reflection, and thus off-axis, as may be performed during projection lithography. Thus, depth of focus may be anamorphic wafer-side where the optical output of the lithography tool is received, and may be isomorphic when wafer-side and reflected to the wafer. Accordingly, high numerical aperture lithography tools may be designed to have anamorphic numerical apertures, and thus defocus properties, on the mask-side. However, such mask imaging techniques are not able to replicate the wafer-side defocus behavior, which is isomorphic. Accordingly, such techniques are not able to emulate the imaging properties at the wafer.

In some embodiments, a light source may be used to generate light that illuminates the photomask, and a microscope-like optic may be used to capture a high magnification electronic image of the photomask. The generated image of the mask may be inspected to assess a quality of the mask in terms of metrics such as uniformity, fidelity, and defectivity. Accordingly, microscopy operations disclosed herein may include one or more imaging operations used to inspect and verify an integrity of a photomask, and ensure the photomask may be used for subsequent lithography operations.

Imaging of such photomasks may be performed using specially configured microscopes that emulate optical characteristics of lithography tools used during the actual lithography operations performed during chip production. Accordingly, the optics used during photomask evaluation may be configured to emulate and evaluate potential impacts of defects in the photomask on such chip production. Conventional techniques for imaging such photomask in the case of high numerical aperture (NA) EUV lithography where the lithography system is anamorphic (i.e. the magnification differs in the x and y directions) remain limited because they are not able to emulate lithographic behavior at the wafer, which may have an isomorphic depth of focus, while also being capable of providing anamorphic depth of focus at a mask layer for mask imaging operations.

Embodiments disclosed herein provide anamorphic depth of focus for imaging of a lithography mask layer, while also being capable of emulating isomorphic depth of focus at a wafer that will undergo lithography operations. As will be discussed in greater detail below, optical elements included in a focusing device may be configured to implement different magnification parameters in different directions of an imaging plane, thus providing configurability of an anamorphic ratio used when imaging such a mask layer. For example, there may be a difference of a factor of two of demagnification between different directions of the imaging plane, and the difference in depth of focus between the two directions at the mask layer may be a factor of four. Optical elements disclosed herein may be configured to dynamically and configurably implement such anamorphic parameters. Such optical elements may be diffractive optics, such as zone plates, that are configured to implement such magnification parameters for their respective directions of the imaging plane. Accordingly, actuation and positioning of these optical elements may be configured to achieve a designated anamorphic ratio specified by designated anamorphic parameters.

Moreover, as will be discussed in greater detail below, such focusing devices may also include additional optical elements configured to provide additional magnification for such mask layer imaging. In various embodiments, imaging of mask layers in a manner compatible with digital imaging sensors uses a relatively high magnification power. Embodiments disclosed herein are configured to provide such high magnification power while also implementing the desired anamorphic ratio for imaging. Furthermore, embodiments disclosed herein provide such imaging capabilities without the use of an additional computational layer or computational approximations used by conventional techniques to emulate lithography operations. Accordingly, embodiments disclosed herein provide such capabilities for anamorphic mask imaging via the optical elements, thus providing true anamorphic imaging.

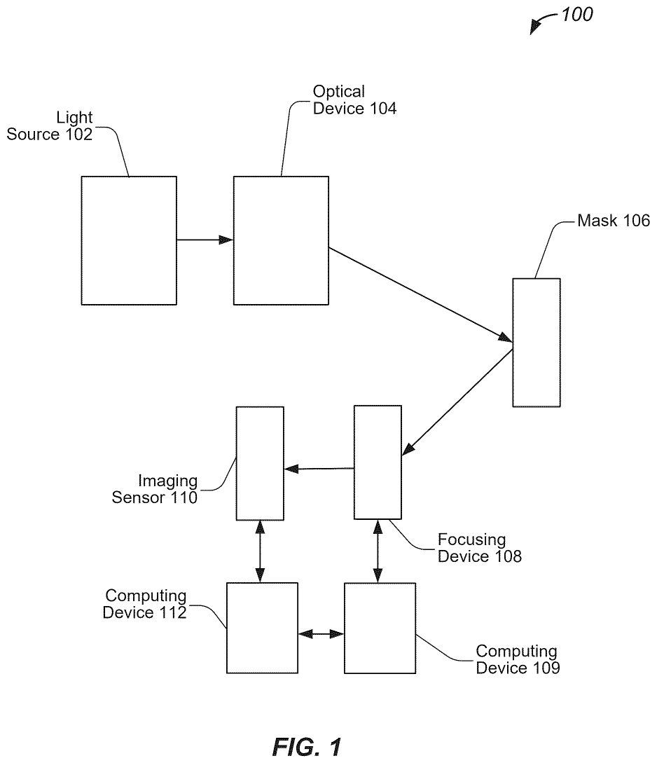

FIG. 1 illustrates an example of a system for anamorphic imaging, configured in accordance with some embodiments. As discussed above, embodiments disclosed herein provide anamorphic magnification and focusing for lithography mask imaging such that depth of focus is controllable and uniform in two different directions of the mask plane and an associated imaging plane. Accordingly, a system, such as system 100, may be configured to provide true anamorphic lithography imaging for a target mask that may have different depths of focus in different directions of the mask plane.

In various embodiments, system 100 includes light source 102 which is configured to generate light used for lithography operations described herein. In various embodiments, light source 102 is configured to generate EUV light. Moreover, light source 102 may be configured to generate EUV light based on the generation of a laser produced plasma. In some embodiments, light source 102 is configured to generate EUV light based on the generation of discharge produced plasma. It will be appreciated that any suitable technique for generating EUV light is contemplated and disclosed herein. Moreover, while various embodiments describe the use of EUV light, any suitable wavelengths of light may be used for lithography applications.

System 100 additionally includes optical device 104 which is configured to receive an optical output from light source 102. In various embodiments, optical device 104 may include one or more optical elements configured to collect light from light source 102, and focus the collected light towards a target, such as mask 106. Accordingly, optical device 104 may be configured as a focusing device that includes a collector mirror and one or more other optical elements, such as a lens, to focus light from light source 102 at mask 106. a collected beam of light based on the collected light. In this way, optical device 104 may be configured to illuminate mask 106 for various lithography operations, such as inspection of mask 106 which may be disposed on a wafer that will undergo lithography etching operations. In various embodiments, optical device 104 may be included in a housing which is configured to provide mechanical and structural support for optical device 104 and components of optical device 104.

System 100 further includes focusing device 108 which is configured to provide independent focusing along two directions of an imaging plane associated with the mask plane. As will be discussed in greater detail below, focusing device 108 may include diffractive optics configured to be independently actuated to independently adjust magnification and focusing in two different directions of the imaging plane. Accordingly, positioning of the diffractive optics included in focusing device 108 may be configured to implement an anamorphic magnification ratio to the reflected image of mask 106 that is provided to imaging sensor 110. As will be discussed in greater detail below, elements included in focusing device 108 may be actuated and positioned to adjust focusing provided by focusing device 108, and such focusing may be controlled via control signals generated by a computing device, such as computing device 109. Accordingly, computing device 109 may be configured to include a processor and memory configured to generate control signals for focusing device 108 which may cause adjustments in positions of elements within focusing device 108 to focus an image provided to imaging sensor 110 discussed in greater detail below. In this way, focusing device 108 provides true anamorphic capabilities for imaging components of a lithography system, such as system 100.

As similarly discussed above, system 100 further includes imaging sensor 110 which is configured to capture images of mask 106 based on the light provided by focusing device 108. Accordingly, light may be provided from optical device 104 to mask 106, may reflect off of mask 106 and be focused by focusing device 108. Imaging sensor 110 may capture an image of mask 106 that has been focused by focusing device 108. In various embodiments, imaging sensor 110 is a charge-coupled device (CCD) camera or a complementary metal-oxide-semiconductor (CMOS) camera. It will be appreciated that any suitable imaging device may be used.

In various embodiments, imaging sensor 110 may capture the image as a digital file that is provided to computing device 112 via a communications interface. Accordingly, computing device 112 may be a computer or other computing system that includes one or more processors and memory configured to communicate with imaging sensor 110 and receive imaging data from imaging sensor 110 where such imaging data includes the captured image of mask 106. Moreover, computing device 112 may also be configured to provide data to imaging sensor 110, such as one or more data values configured to implement exposure parameters such as sensitivity and time settings. In various embodiments, computing device 112 may be communicatively coupled to computing device 109, or computing device 112 and computing device 109 may be integrated into a single computing device. Thus, according to some embodiments, a single computing device is used to process imaging data from imaging sensor 110 and generate control signals for actuation of elements of focusing device 108.

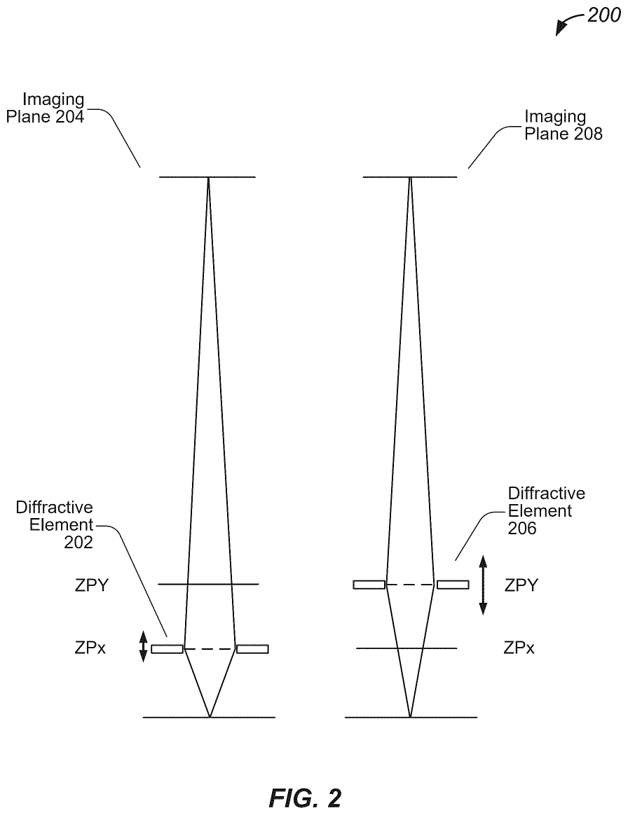

FIG. 2 illustrates an example of a device for anamorphic imaging, configured in accordance with some embodiments. As similarly discussed above, embodiments disclosed herein enable anamorphic magnification and focusing for lithography mask imaging such that depth of focus is controllable and uniform in two different directions of the mask plane and an associated imaging plane. As will be discussed in greater detail below, optical elements included in a focusing device may be configured to apply designated magnification parameters in a designated direction. Accordingly, different optical elements may be used to apply different magnification parameters in different directions of an imaging plane when imaging is performed for lithography operations, such as imaging of a mask used in such lithography operations.

As shown in FIG. 2, diffractive element 202 may be configured to apply first magnification parameters in a first direction of an imaging plane. For example, diffractive element 202 may be configured to apply a first designated amount of magnification in an x/z plane of an imaging sensor. In one example, diffractive element 202 may be a diffractive optic, such as a cylindrical zone plate, which is configured to use optical diffraction for focusing and magnification. Thus, diffractive elements disclosed herein may be diffractive optics that are configured to implement a designated amount and type of optical diffraction. Accordingly, Fresnel zones of the diffractive element 202 may be configured to generate the first designated amount of magnification in the first designated direction of the imaging plane, such as imaging plane 204. In some embodiments, diffractive element 202 may be a cylindrical zone plate wherein the zones have relatively little to no curvature and thus diffract and focus light in substantially one direction.

As also shown in FIG. 2, an additional diffractive element, such as diffractive element 206, may be configured to apply second magnification parameters in a second direction of an imaging plane, such as imaging plane 208. For example, diffractive element 206 may be configured to apply a second designated amount of magnification in a y/z plane of an imaging sensor. Accordingly, the first direction of magnification may be orthogonal to the second direction of magnification. As similarly discussed above, diffractive element 206 may be a diffractive optic, such as a cylindrical zone plate, that is configured to use optical diffraction for focusing and magnification. Accordingly, Fresnel zones of the of diffractive element 206 may be configured to generate the second designated amount of magnification in the second designated direction of the imaging plane, such as imaging plane 208.

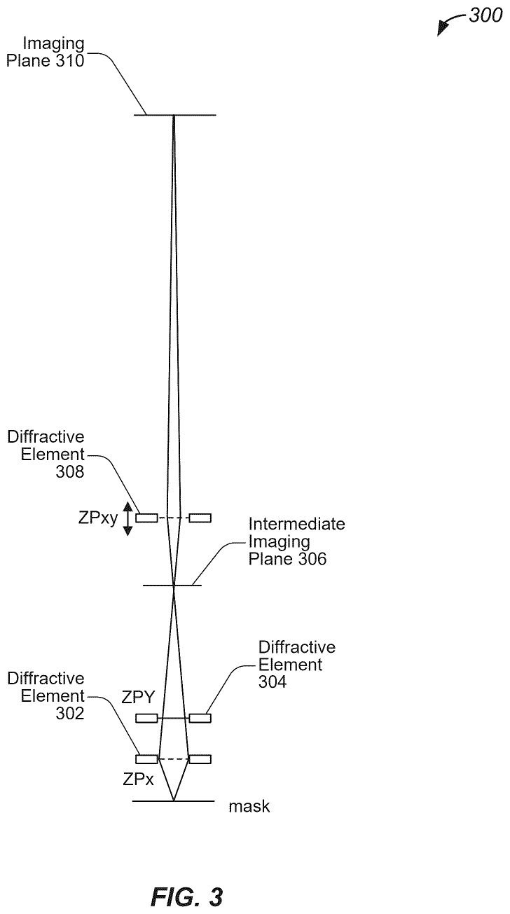

As will be discussed in greater detail below, diffractive element 202 and diffractive element 206 may be implemented in combination for the same imaging plane. Accordingly, while FIG. 2 illustrates a diagram for an x/z plane associated with a direction of magnification for diffractive element 202 as well as a diagram for a y/z plane associated with a direction of magnification for diffractive element 206, it will be appreciated that the two have been shown separately for illustrative purposes for each respective direction, and the two diffractive elements may be implemented in combination and in series, as similarly discussed below with reference to FIGS. 3-5. Moreover, each of diffractive element 202 and diffractive element 206 may be independently actuated to adjust focus and magnification generated by each of diffractive element 202 and diffractive element 206 in an image provided to an imaging sensor. In this way, combinations of diffractive elements may be implemented to achieve an anamorphic ratio in the image provided to the imaging sensor, as well as provide focusing such that the image maintains a uniform depth of focus across the entire image of the mask.

FIG. 3 illustrates another example of a device for anamorphic imaging, configured in accordance with some embodiments. As similarly discussed above, embodiments disclosed herein enable anamorphic magnification and focusing for lithography mask imaging such that depth of focus is controllable and uniform in two different directions of the mask plane and an associated imaging plane. As will be discussed in greater detail below, optical elements included in a focusing device, such as focusing device 300, may be configured to apply designated magnification parameters in a designated direction. Accordingly, a combination of different optical elements may be used to apply multiple magnification parameters in different directions of an imaging plane when imaging is performed for lithography operations.

As shown in FIG. 3, diffractive element 302 may be configured to apply first magnification parameters in a first direction of an imaging plane. For example, diffractive element 302 may be configured to apply a first designated amount of magnification in an x/z plane of an imaging sensor. In one example, diffractive element 302 may be a diffractive optic, such as a cylindrical zone plate, which is configured to use optical diffraction for focusing and magnification in one direction. Accordingly, Fresnel zones of diffractive element 302 may be configured to generate the first designated amount of magnification in the first designated direction of the imaging plane, such as imaging plane 310. As disclosed herein, the imaging plane may be defined based on an imaging plane of an imaging sensor included in an imaging device. For example, a CCD or CMOS sensor included in a digital camera may have an active area, and the imaging plane may be the plane at which the pixels within the active area are positioned. Accordingly, imaging plane 310 may also be a plane at which pixels of an imaging sensor reside.

In various embodiments, an additional diffractive element, such as diffractive element 304, may be configured to apply second magnification parameters in a second direction of an imaging plane, such as imaging plane 310. For example, diffractive element 304 may be configured to apply a second designated amount of magnification in a y/z plane of an imaging sensor. As similarly discussed above, diffractive element 304 may be a diffractive optic, such as a cylindrical zone plate, that is configured to use optical diffraction for focusing and magnification.

According to some embodiments, an additional diffractive element, such as diffractive element 308, may be positioned after a designated distance. In one example, light that passes through diffractive element 302 and diffractive element 304 may converge to form an intermediate image at intermediate imaging plane 306, and then pass through diffractive element 308. In some embodiments, diffractive element 308 is configured to provide additional magnification for the image formed at imaging plane 310. Diffractive element 308 may be a diffractive optic, such as a zone plate lens, that is configured to use optical diffraction for focusing and magnification in both the x and y directions simultaneously. Accordingly, diffractive element 308 may be configured to have a designated magnification parameter that provides magnification in addition to that provided by diffractive element 302 and diffractive element 304. In this way, in addition to the anamorphic imaging discussed above, focusing device 300 may also provide additional magnification of the image provided to an imaging sensor at imaging plane 310.

As similarly discussed above, each of diffractive element 302, diffractive element 304, and diffractive element 308 may be independently actuated and positioned. Accordingly, diffractive element 302, diffractive element 304, and diffractive element 308 may be implemented within a housing and may also be coupled to the housing via positioning devices such as positioning rails or any other suitable positioning device configured to provide mechanical support for the diffractive elements as well as change their position along the optical axis of focusing device 300. In various embodiments, changing a position of a diffractive element may include moving the diffractive element a linear distance along the optical axis of focusing device 300.

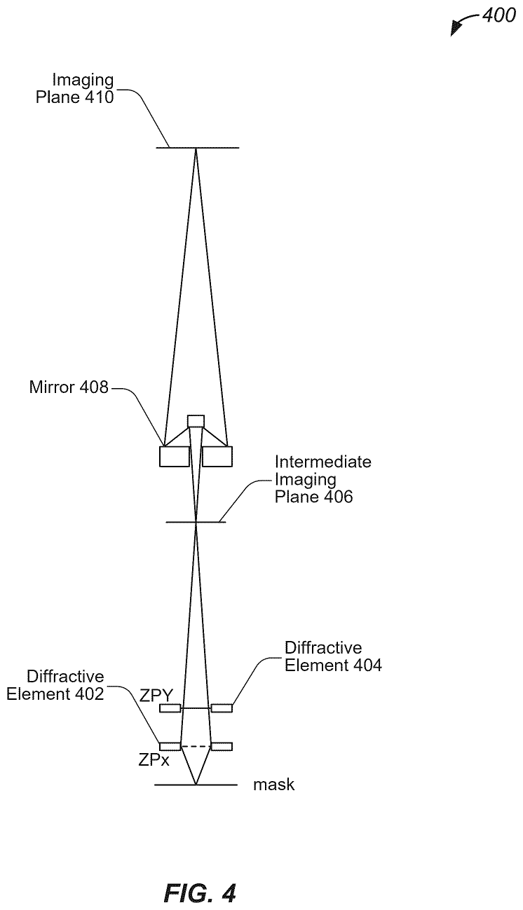

FIG. 4 illustrates an additional example of a device for anamorphic imaging, configured in accordance with some embodiments. As similarly discussed above, embodiments disclosed herein enable anamorphic magnification and focusing for lithography mask imaging. As will be discussed in greater detail below, optical elements included in a focusing device, such as focusing device 400, may be configured to apply designated magnification parameters in a designated direction. Moreover, additional magnification may be provided by one or more mirrors included in focusing device 400.

As shown in FIG. 4, diffractive element 402 may be configured to apply first magnification parameters in a first direction of an imaging plane. For example, diffractive element 402 may be configured to apply a first designated amount of magnification in an x/z plane of an imaging sensor. As similarly discussed above, diffractive element 402 may be a diffractive optic, such as a cylindrical zone plate, that is configured to use optical diffraction for focusing and magnification. Moreover, an additional diffractive element, such as diffractive element 404, may be configured to apply second magnification parameters in a second direction of an imaging plane, such as imaging plane 410. As similarly discussed above, imaging plane 410 may be defined based on an imaging plane of an imaging sensor included in an imaging device. Moreover, diffractive element 404 may be configured to apply a second designated amount of magnification in a y/z plane of an imaging sensor. As similarly discussed above, diffractive element 404 may be a diffractive optic, such as a cylindrical zone plate, that is configured to use optical diffraction for focusing and magnification.

In various embodiments, one or more mirrors may be included in focusing device 400 that are configured to provide additional magnification of the image provided to an imaging sensor at imaging plane 410. More specifically, mirror 408 may be positioned after intermediate imaging plane 406, and may be configured to receive light from diffractive element 404 and magnify an image represented in the received light in accordance with a designated magnification parameter. In various embodiments, mirror 408 includes multiple mirrors that are configured to implement such magnification. For example, mirror 408 may include two mirrors that are configured as a two-bounce Schwarschild-type mirror. In various embodiments, a position of either mirror 408 or an imaging sensor positioned at imaging plane 410 may be adjusted for magnification and/or focusing purposes. More specifically, a position of the imaging sensor itself may be adjusted until a uniform focus is achieved for the image received by the imaging sensor.

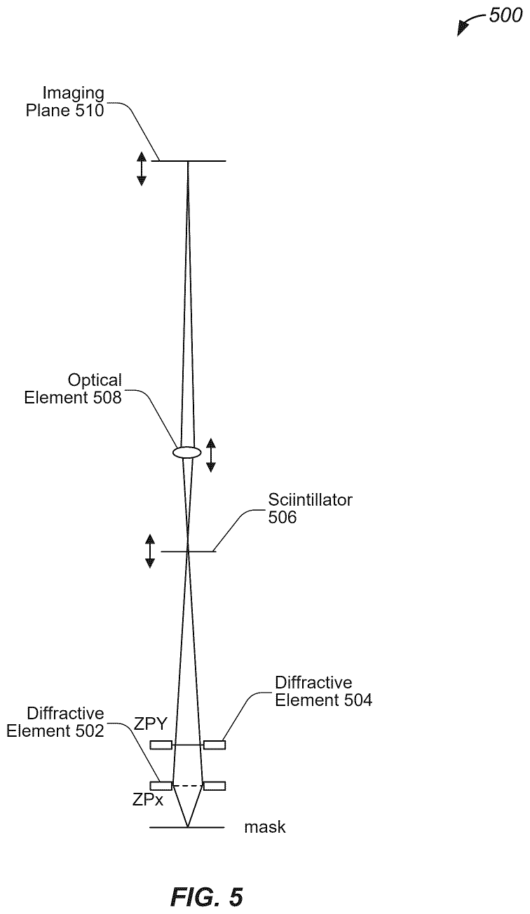

FIG. 5 illustrates another example of a device for anamorphic imaging, configured in accordance with some embodiments. As similarly discussed above, embodiments disclosed herein enable anamorphic magnification and focusing for lithography mask imaging. As will be discussed in greater detail below, optical elements included in a focusing device, such as focusing device 500, may be configured to apply designated magnification parameters in a designated direction. Moreover, additional magnification may be provided via implementation of additional optical elements, such as a conventional refraction lens.

As shown in FIG. 5, diffractive element 502 may be configured to apply first magnification parameters in a first direction of an imaging plane. For example, diffractive element 502 may be configured to apply a first designated amount of magnification in an x/z plane of an imaging sensor. Moreover, an additional diffractive element, such as diffractive element 504, may be configured to apply second magnification parameters in a second direction of an imaging plane, such as imaging plane 510. As similarly discussed above, imaging plane 510 may be defined based on an imaging plane of an imaging sensor included in an imaging device. Moreover, diffractive element 504 may be configured to apply a second designated amount of magnification in a y/z plane of an imaging sensor.

In various embodiments, an intermediate image may be converted to a real image via implementation of an optical converter, such as scintillator 506. More specifically, scintillator 506 may be configured to convert EUV photons to a different optical regime of light, such as visible light. The converted light may then be provided to optical element 508 which may be configured to apply a designated amount of magnification in accordance with a designated magnification parameter. Accordingly, optical element 508 may be a lens, a diffractive optic, or any other suitable optical element configured to magnify light received from scintillator 506. The magnified light may subsequently be provided to an imaging sensor positioned at imaging plane 510. In various embodiments, a position of either scintillator 506, optical element 508, or the imaging sensor positioned at imaging plane 510 may be adjusted for magnification and/or focusing purposes.

Moreover, in one example where scintillator 506 is configured to convert EUV light to visible light, a camera including an imaging sensor configured to capture visible light may be used. In this way, various widely available consumer cameras may be used to provide the image sensor at imaging plane 510. In another example, scintillator 506 may be configured to convert EUV light to an electron output. In this example, the imaging device at imaging plane 510 may be an electron-based imaging system that captures an electron-based image.

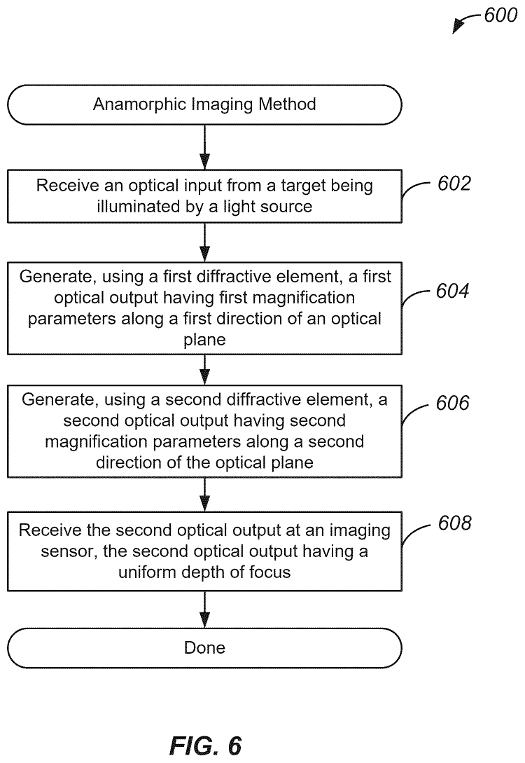

FIG. 6 illustrates an example of a method for anamorphic imaging, performed in accordance with some embodiments. As similarly discussed above, embodiments disclosed herein enable anamorphic magnification and focusing for lithography mask imaging. As will be discussed in greater detail below, a method, such as method 600, may be performed to apply designated magnification parameters in multiple directions of an imaging plane provided to an imaging sensor used for imaging of such lithography masks or other lithography targets.

Method 600 may perform operation 602 during which an optical input may be received from a target being illuminated by a light source. As similarly discussed above, the target may be a target of EUV lithography operations. More specifically, the target may be a mask disposed on a target substrate that will be subjected to such EUV lithography operations. Light from a light source and optical device may be reflected off of the target, and be received at the first diffractive element. Accordingly, the received optical input may include a reflected image of the mask or any suitable target that is being illuminated.

Method 600 may perform operation 604 during which a first optical output may be generated using a first diffractive element. In various embodiments, the first optical output may have first magnification parameters along a first direction of an optical plane. More specifically, the first diffractive element may be a diffractive optic that includes optical features configured to implement optical diffraction to generate a designated amount of magnification in the first direction of the optical plane. The designated amount may be determined by the first magnification parameters, which may have been determined by an entity, such as a manufacturer, during design and manufacture of components such as the focusing device, and may be determined based, at least in part, on dimensions and a position of the imaging sensor. Accordingly, the first optical output may include the reflected image magnified based on the first magnification parameters.

Method 600 may perform operation 606 during which a second optical output may be generated using a second diffractive element. In various embodiments, the second optical output may have second magnification parameters along a second direction of the optical plane. As similarly discussed above, the second diffractive element also may include optical features configured to implement optical diffraction to generate a designated amount of magnification in the second direction of the optical plane. The designated amount may be determined by the second magnification parameters, which may have been determined by an entity, such as a manufacturer, during design and manufacture of components such as the focusing device, and may be determined based, at least in part, on dimensions and a position of the imaging sensor.

Thus, according to various embodiments, the second optical output may include the reflected image magnified based on the first magnification parameters as well as the second magnification parameters. As similarly discussed above, the second direction may be different than the first direction. In this way, the first diffractive element and the second diffractive element may independently apply different magnification parameters to different dimensions of the imaging plane associated with the imaging sensor.

Method 600 may perform operation 608 during which the second optical output may be received at an imaging sensor. In various embodiments, the second optical output has a uniform depth of focus across the imaging sensor. The uniform depth of focus may be ensured to be uniform in the two directions by ensuring that the angular range of light from the first and second optical outputs propagating towards the imaging sensor are substantially the same. As similarly discussed above, the second optical output may include a reflected image of a mask disposed on a wafer that will undergo EUV lithography operations. Accordingly, the second optical output provided to the imaging sensor may provide such image magnified in accordance with the first and second magnification parameters to obtain a uniform depth of focus across the entire active area of the imaging sensor such that the entire image is in focus at the imaging sensor.

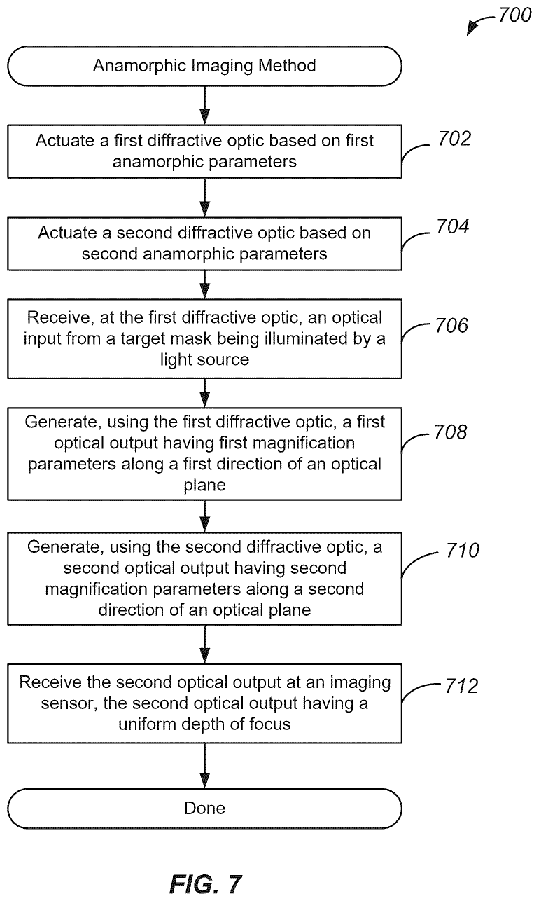

FIG. 7 illustrates another example of a method for anamorphic imaging, performed in accordance with some embodiments. As similarly discussed above, embodiments disclosed herein enable anamorphic magnification and focusing for lithography mask imaging. As will be discussed in greater detail below, a method, such as method 700, may be performed to configure and position optical elements used to apply designated magnification parameters in multiple directions of an imaging plane for imaging of such lithography masks or other lithography targets.

Method 700 may perform operation 702 during which a first diffractive optic may be actuated based on first anamorphic parameters. As similarly discussed above, optical elements, such as diffractive optics, may be dynamically positioned to ensure a focused image generated by the first diffractive optic is positioned at an imaging sensor being used to image the lithography mask. Accordingly, during operation 702, one or more positional adjustments may be made to the first diffractive optic.

In various embodiments, the first diffractive optic is a first zone plate that has first diffractive elements configured to implement first magnification parameters. As similarly discussed above, the first zone plate may be moved via a positioning device, such as focusing rails within a focusing device, and may be moved until focus is achieved at the imaging sensor. As also discussed above, positioning of the first diffractive optic may be controlled via a computing device and one or more mechanical motors of the positioning device. In some embodiments, the positioning may be performed via a manual input received from an entity, such as a user, via one or more manual focus controls.

Method 700 may perform operation 704 during which a second diffractive optic may be actuated based on second anamorphic parameters. Accordingly, the second diffractive optic may be dynamically positioned to ensure a focused image generated by the second diffractive optic is positioned at the imaging sensor. Thus, during operation 704, one or more positional adjustments may be made to the second diffractive optic. As also discussed above, the second diffractive optic may be a second zone plate that has second diffractive elements configured to implement second magnification parameters. Accordingly, the second zone plate may be moved via a positioning device, such as focusing rails, within the focusing device, and may be moved until focus is achieved at the imaging sensor. As also discussed above, positioning of the second diffractive optic may be controlled via a computing device and one or more mechanical motors of the positioning device. In some embodiments, the positioning may be performed via a manual input received from an entity, such as a user, via one or more manual focus controls.

Method 700 may perform operation 706 during which an optical input may be received at the first diffractive optic from a target mask being illuminated by a light source. As similarly discussed above, the target may be a mask disposed on a target substrate that will be subjected to such EUV lithography operations. EUV light from a light source and optical device may be reflected off of the target, and may be received at the first diffractive optic. Accordingly, the received optical input may include a reflected image of the mask or any suitable target that is being illuminated.

Method 700 may perform operation 708 during which a first optical output may be generated using the first diffractive optic. The first optical output may have first magnification parameters along a first direction of an optical plane. More specifically, the first diffractive optic may be a zone plate that is configured to implement optical diffraction to generate a first amount of magnification in the first direction of the imaging plane of the imaging sensor. The first amount may be determined by the first magnification parameters, which may have been determined by an entity, such as a manufacturer, and may be determined in accordance with an anamorphic ratio specified by the manufacturer. In various embodiments, such an anamorphic ratio may be determined based, at least in part, on dimensions and an aspect ratio of the imaging sensor. Accordingly, the first optical output may include the reflected image magnified based on the first magnification parameters.

Method 700 may perform operation 710 during which a second optical output may be generated using the second diffractive optic. The second optical output may have second magnification parameters along a second direction of an optical plane. More specifically, the second diffractive optic may also be a zone plate that is configured to implement optical diffraction to generate a second amount of magnification in the second direction of the imaging plane of the imaging sensor. The second amount may be determined by the second magnification parameters, which may also have been determined by an entity, such as a manufacturer, and may be determined in accordance with the anamorphic ratio specified by the manufacturer. Accordingly, the second optical output may include the reflected image magnified based, at least in part, on the second magnification parameters. More specifically, the second optical output may include the reflected image magnified based on both the first magnification parameters as well as the second magnification parameters, and in accordance with the specified anamorphic ratio.

Method 700 may perform operation 712 during which the second optical output may be received at an imaging sensor. As similarly discussed above, the first diffractive optic and the second diffractive optic may independently apply different magnification parameters to different dimensions and directions of the imaging plane associated with the imaging sensor. In various embodiments, the second optical output received at the imaging sensor may thus be magnified based on a combination of the first and second magnification parameters, thus achieving anamorphic imaging with uniform depth of focus at the imaging sensor.

As similarly discussed above, the second optical output may include a reflected image of a mask disposed on a substrate that will undergo EUV lithography operations. Accordingly, the second optical output provided to the imaging sensor may provide such image magnified in accordance with the first and second magnification parameters thus providing an anamorphic image with uniform (isomorphic) depth of focus in the two directions.

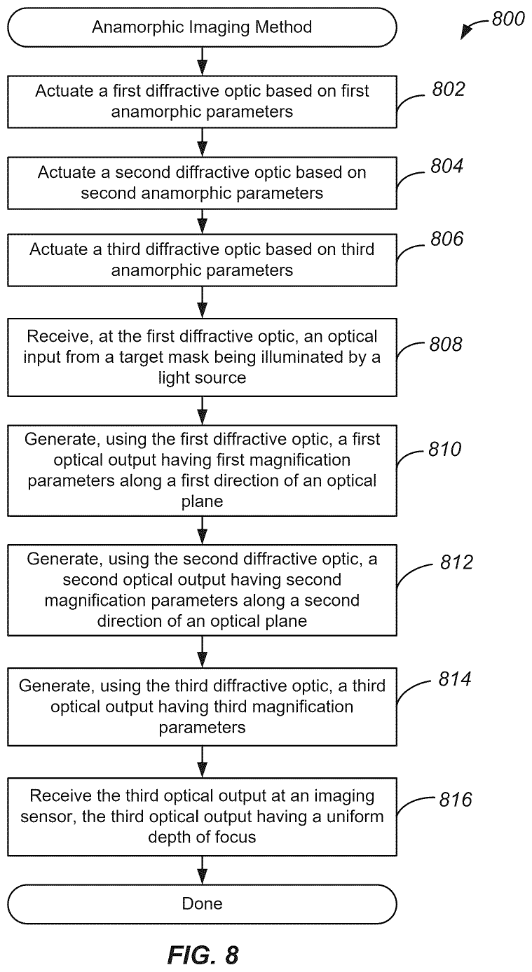

FIG. 8 illustrates an example of a method for anamorphic imaging, performed in accordance with some embodiments. As similarly discussed above, embodiments disclosed herein enable anamorphic magnification and focusing for lithography mask imaging. As will be discussed in greater detail below, a method, such as method 700, may be performed to configure and position optical elements used to apply designated magnification parameters in multiple directions of an imaging plane, as well as additional optical elements for additional magnification used in such imaging.

Method 800 may perform operation 802 during which a first diffractive optic may be actuated based on first anamorphic parameters. As similarly discussed above, optical elements, such as diffractive optics, may be dynamically positioned to ensure a focused image generated by the first diffractive optic is positioned at an imaging sensor being used to image the lithography mask. Accordingly, during operation 802, one or more positional adjustments may be made to the first diffractive optic. As similarly discussed above, the first diffractive optic may be a first zone plate that has first diffractive elements configured to implement first magnification parameters, and the first zone plate may be moved via a positioning device, such as focusing rails within a focusing device, and may be moved until focus is achieved at the imaging sensor.

Method 800 may perform operation 804 during which a second diffractive optic may be actuated based on second anamorphic parameters. Accordingly, the second diffractive optic may be dynamically positioned to ensure a focused image generated by the second diffractive optic is positioned at the imaging sensor. Thus, during operation 804, one or more positional adjustments may be made to the second diffractive optic. As also discussed above, the second diffractive optic may be a second zone plate that has second diffractive elements configured to implement second magnification parameters, and the second zone plate may be moved via a positioning device, such as focusing rails, within the focusing device, and may be moved until focus is achieved at the imaging sensor.

Method 800 may perform operation 806 during which a third diffractive optic may be actuated based on third anamorphic parameters. As similarly discussed above, an optical output of the second diffractive optic may converge at an intermediate imaging plane and then pass through a third diffractive optic that is configured to provide additional magnification of the image generated by both the first diffractive optic and the second diffractive optic. Accordingly, the third diffractive optic may be positioned to implement the designated amount of additional magnification to be applied to the image. Thus, during operation 806, one or more positional adjustments may be made to the third diffractive optic which may be a third zone plate that has third diffractive elements configured to implement third magnification parameters. As similarly discussed above, the third zone plate may be moved via a positioning device, such as focusing rails, until focus is achieved at the imaging sensor.

Method 800 may perform operation 808 during which an optical input may be received at the first diffractive optic from a target mask being illuminated by a light source. As similarly discussed above, the target may be a mask disposed on a substrate that will be used during EUV projection lithography operations. EUV light from a light source and optical device may be reflected off of the target mask, and may be received at the first diffractive optic. Accordingly, the received optical input may include a reflected image of the mask or any suitable target that is being illuminated.

Method 800 may perform operation 810 during which a first optical output may be generated using the first diffractive optic. The first optical output may have first magnification parameters along a first direction of an optical plane. As discussed above, the first diffractive optic may be a zone plate that is configured to implement optical diffraction to generate a first amount of magnification in the first direction of the imaging plane of the imaging sensor. Accordingly, the first optical output may include the reflected image magnified based on the first magnification parameters.

Method 800 may perform operation 812 during which a second optical output may be generated using the second diffractive optic. The second optical output may have second magnification parameters along a second direction of an optical plane. More specifically, the second diffractive optic may also be a zone plate that is configured to implement optical diffraction to generate a second amount of magnification in the second direction of the imaging plane of the imaging sensor. Accordingly, the second optical output may include the reflected image magnified based, at least in part, on the second magnification parameters. More specifically, the second optical output may include the reflected image magnified based on both the first magnification parameters as well as the second magnification parameters, and in accordance with the specified anamorphic ratio.

Method 800 may perform operation 814 during which a third optical output may be generated using the third diffractive optic. As similarly discussed above, the third optical output may have third magnification parameters that apply a designated amount of magnification to the image. More specifically, the third diffractive optic may also be a zone plate that is configured to implement optical diffraction to generate the third amount of magnification. In some embodiments, the third amount of magnification may be applied isomorphically, and thus in first and second directions. It will be appreciated that the third diffractive optic may be configured to apply the third amount of magnification in any suitable manner. For example, the third diffractive optic may apply such third magnification parameters anamorphically. Accordingly, the third optical output may include the reflected image magnified based, at least in part, on the third magnification parameters. More specifically, the third optical output may include the reflected image magnified based on the first magnification parameters, the second magnification parameters, and the third magnification parameters.

Method 800 may perform operation 816 during which the third optical output may be received at an imaging sensor. As similarly discussed above, the first diffractive optic and the second diffractive optic may independently apply different magnification parameters to different dimensions and directions of the imaging plane associated with the imaging sensor, and the third diffractive optic may provide additional magnification. Accordingly, the third optical output received at the imaging sensor may thus be magnified based on a combination of the first and second magnification parameters as well as the third magnification parameters, thus achieving anamorphic imaging with uniform depth of focus at the imaging sensor with additional magnification.

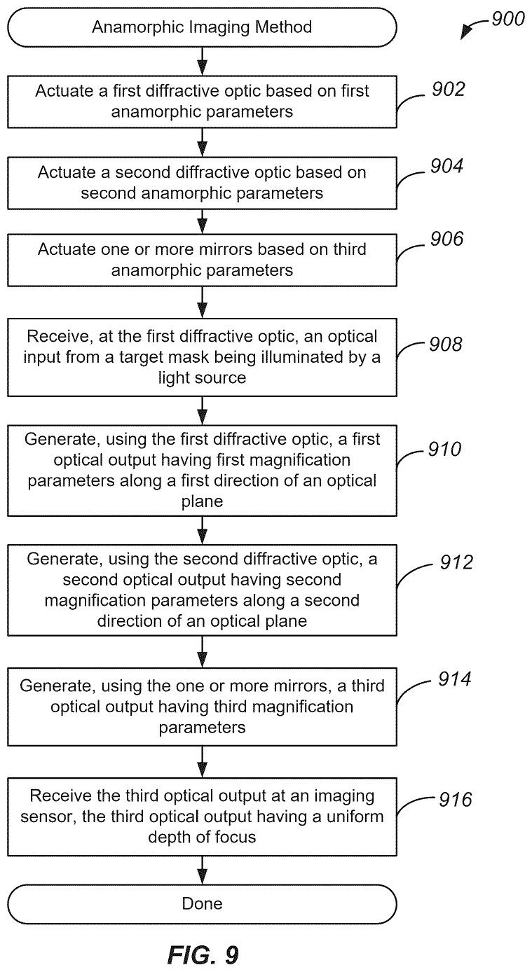

FIG. 9 illustrates an additional example of a method for anamorphic imaging, performed in accordance with some embodiments. As will be discussed in greater detail below, a method, such as method 900, may be performed to configure and position optical elements used to apply designated magnification parameters in multiple directions of an imaging plane, as well as one or more mirrors configured to provide additional magnification used in such imaging.

Method 900 may perform operation 902 during which a first diffractive optic may be actuated based on first anamorphic parameters. As similarly discussed above, one or more positional adjustments may be made to the first diffractive optic, which may be a first zone plate that has first diffractive elements configured to implement first magnification parameters. In various embodiments, the first zone plate may be moved via a positioning device until focus is achieved at the imaging sensor.

Method 900 may perform operation 904 during which a second diffractive optic may be actuated based on second anamorphic parameters. As similarly discussed above, one or more positional adjustments may be made to the second diffractive optic, which may be a second zone plate that has second diffractive elements configured to implement second magnification parameters. Accordingly, the second zone plate may be moved via a positioning device until focus is achieved at the imaging sensor.

Method 900 may perform operation 906 during which a second diffractive optic may be actuated based on second anamorphic parameters. As similarly discussed above, an optical output of the second diffractive optic may converge at an intermediate imaging plane and then be provided to one or more mirrors that are configured to provide additional magnification of the image generated by both the first diffractive optic and the second diffractive optic. For example, the one or more mirrors may include a combination of mirrors configured to provide such additional magnification. In one example, the combination of mirrors is implemented as a two-bounce Schwarschild-type mirror device. Accordingly, the one or more mirrors may be positioned to implement the designated amount of additional magnification to be applied to the image. In some embodiments, the position of the one or more mirrors may remain fixed, and a position of the downstream imaging sensor may be adjusted. As similarly discussed above, such movements may be implemented via a positioning device, such as focusing rails, until focus is achieved at the imaging sensor.

Method 900 may perform operation 908 during which an optical input may be received at the first diffractive optic from a target mask being illuminated by a light source. As similarly discussed above, the target may be a mask disposed on a substrate that will be used during EUV projection lithography operations. EUV light from a light source and optical device may be reflected off of the target mask, and may be received at the first diffractive optic. Accordingly, the received optical input may include a reflected image of the mask or any suitable target that is being illuminated.

Method 900 may perform operation 910 during which a first optical output may be generated using the first diffractive optic. The first optical output may have first magnification parameters along a first direction of an optical plane. As discussed above, the first diffractive optic may be a zone plate that is configured to implement optical diffraction to generate a first amount of magnification in the first direction of the imaging plane of the imaging sensor. Accordingly, the first optical output may include the reflected image magnified based on the first magnification parameters.

Method 900 may perform operation 912 during which a second optical output may be generated using the second diffractive optic. The second optical output may have second magnification parameters along a second direction of an optical plane. More specifically, the second diffractive optic may also be a zone plate that is configured to implement optical diffraction to generate a second amount of magnification in the second direction of the imaging plane of the imaging sensor. Accordingly, the second optical output may include the reflected image magnified based, at least in part, on both the first magnification parameters as well as the second magnification parameters, and in accordance with the specified anamorphic ratio.

Method 900 may perform operation 914 during which a third optical output may be generated using the third diffractive optic. As similarly discussed above, the third optical output may have third magnification parameters that apply a designated amount of magnification to the image. More specifically, the one or more mirrors may have curvatores and optical parameters configured to generate the third amount of magnification. In some embodiments, the third amount of magnification may be applied isomorphically, and thus equally in the first and second directions. It will be appreciated that the third diffractive optic may be configured to apply the third amount of magnification in any suitable manner and ratio of directions. Accordingly, the third optical output may include the reflected image magnified based, at least in part, on the third magnification parameters. More specifically, the third optical output may include the reflected image magnified based on the first magnification parameters, the second magnification parameters, and the third magnification parameters.

Method 900 may perform operation 916 during which the third optical output may be received at an imaging sensor. As similarly discussed above, the first diffractive optic and the second diffractive optic may independently apply different magnification parameters to different dimensions and directions of the imaging plane associated with the imaging sensor, and the one or more mirrors may provide additional magnification. Accordingly, the third optical output received at the imaging sensor may thus be magnified based on a combination of the first and second magnification parameters as well as the third magnification parameters, thus achieving anamorphic imaging with uniform depth of focus at the imaging sensor with additional magnification.

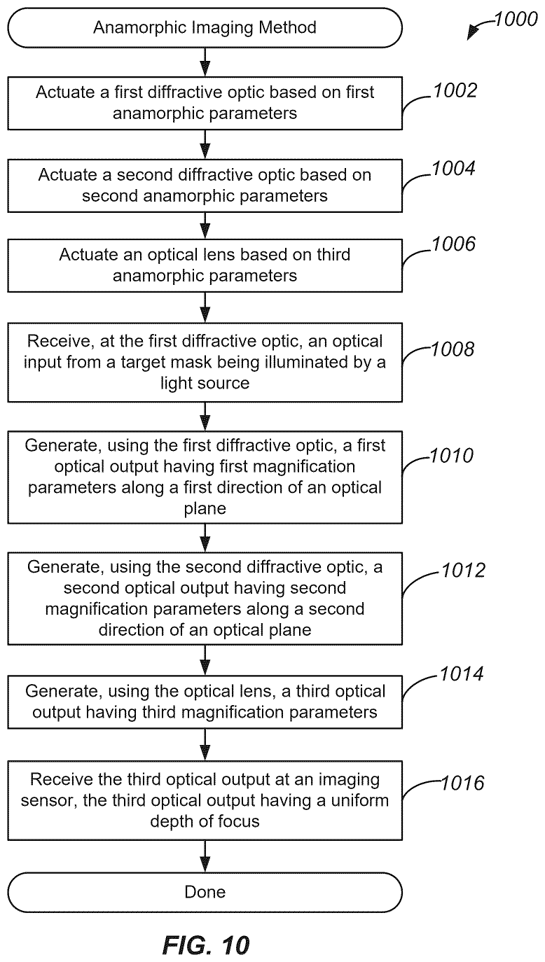

FIG. 10 illustrates another example of a method for anamorphic imaging, performed in accordance with some embodiments. As will be discussed in greater detail below, a method, such as method 1000, may be performed to configure and position optical elements used to apply designated magnification parameters in multiple directions of an imaging plane, as well as one or more mirrors configured to provide additional magnification used in such imaging.

Method 1000 may perform operation 1002 during which a first diffractive optic may be actuated based on first anamorphic parameters. As similarly discussed above, one or more positional adjustments may be made to the first diffractive optic, which may be a first zone plate that has first diffractive elements configured to implement first magnification parameters. In various embodiments, the first zone plate may be moved via a positioning device until focus is achieved at the imaging sensor.

Method 1000 may perform operation 1004 during which a second diffractive optic may be actuated based on second anamorphic parameters. As similarly discussed above, one or more positional adjustments may be made to the second diffractive optic, which may be a second zone plate that has second diffractive elements configured to implement second magnification parameters. Accordingly, the second zone plate may be moved via a positioning device until focus is achieved at the imaging sensor.

Method 1000 may perform operation 1006 during which a second diffractive optic may be actuated based on second anamorphic parameters. As similarly discussed above, an optical output of the second diffractive optic may converge at an intermediate imaging plane and then pass through an optical lens that is configured to provide additional magnification of the image generated by both the first diffractive optic and the second diffractive optic. Accordingly, the optical lens optic may be positioned to implement the designated amount of additional magnification to be applied to the image. Thus, during operation 1006, one or more positional adjustments may be made to the optical lens to implement the third magnification parameters, and such positional adjustments may be made via a positioning device, such as focusing rails, until focus is achieved at the imaging sensor.

Method 1000 may perform operation 1008 during which an optical input may be received at the first diffractive optic from a target mask being illuminated by a light source. As similarly discussed above, the target may be a mask disposed on a substrate that will be used during EUV projection lithography operations. EUV light from a light source and optical device may be reflected off of the target mask, and may be received at the first diffractive optic. Accordingly, the received optical input may include a reflected image of the mask or any suitable target that is being illuminated.

Method 1000 may perform operation 1010 during which a first optical output may be generated using the first diffractive optic. The first optical output may have first magnification parameters along a first direction of an optical plane. As discussed above, the first diffractive optic may be a zone plate that is configured to implement optical diffraction to generate a first amount of magnification in the first direction of the imaging plane of the imaging sensor. Accordingly, the first optical output may include the reflected image magnified based on the first magnification parameters.

Method 1000 may perform operation 1012 during which a second optical output may be generated using the second diffractive optic. The second optical output may have second magnification parameters along a second direction of an optical plane. More specifically, the second diffractive optic may also be a zone plate that is configured to implement optical diffraction to generate a second amount of magnification in the second direction of the imaging plane of the imaging sensor. Accordingly, the second optical output may include the reflected image magnified based, at least in part, on both the first magnification parameters as well as the second magnification parameters, and in accordance with the specified anamorphic ratio.

Method 1000 may perform operation 1014 during which a third optical output may be generated using the optical lens. As similarly discussed above, the third optical output may have third magnification parameters that apply a designated amount of magnification to the image. As similarly discussed above, the second optical output may pass through a scintillator or other optical converter to convert EUV light included in the second optical output to another range of optical wavelengths. In some embodiments, the third amount of magnification may be applied isomorphically, and thus in the first and second directions. It will be appreciated that the third diffractive optic may be configured to apply the third amount of magnification in any suitable manner and ratio of directions. Thus, the third optical output may include the reflected image magnified based, at least in part, on the first magnification parameters, the second magnification parameters, and the third magnification parameters.

Method 1000 may perform operation 1016 during which the third optical output may be received at an imaging sensor. As similarly discussed above, the first diffractive optic and the second diffractive optic may independently apply different magnification parameters to different dimensions and directions of the imaging plane associated with the imaging sensor, and the optical lens may provide additional magnification. Accordingly, the third optical output received at the imaging sensor may thus be magnified based on a combination of the first and second magnification parameters as well as the third magnification parameters, thus achieving anamorphic imaging with uniform depth of focus at the imaging sensor with additional magnification.

Although the foregoing concepts have been described in some detail for purposes of clarity of understanding, it will be apparent that certain changes and modifications may be practiced within the scope of the appended claims. It should be noted that there are many alternative ways of implementing processes, systems, and apparatuses. Accordingly, the present embodiments are to be considered illustrative and not restrictive.

What is claimed is:

1. A system comprising:
a focusing device configured to receive an optical input based on light generated by a light source, the focusing device comprising:
a first diffractive optic configured to receive an optical input based on light generated by a light source, and further configured to generate a first optical output having first magnification parameters along a first direction of an optical plane; and
a second diffractive optic configured to receive the first optical output, and further configured to generate a second optical output having second magnification parameters along a second direction of the optical plane,
wherein the first direction is different than the second direction, and wherein the second optical output has a uniform depth of focus along the first direction and the second direction associated with an imaging plane; and
an imaging device configured to receive the second optical output at the imaging plane.

2. The system of claim 1, wherein the first diffractive optic comprises a first cylindrical zone plate, and wherein the second diffractive optic comprises a second cylindrical zone plate.

3. The system of claim 2, wherein the first diffractive optic and the second diffractive optic are configured to be adjustably positioned along an optical axis.

4. The system of claim 1 further comprising:
a third diffractive optic configured to generate a third optical output having third magnification parameters.

5. The system of claim 4, wherein the third diffractive optic is positioned after an intermediate image generated by the second diffractive optic.

6. The system of claim 5, wherein the third diffractive optic is a zone plate lens configured to provide magnification in both the first direction and the second direction.

7. The system of claim 4 further comprising:
a mirror configured to generate a third optical output having third magnification parameters.

8. The system of claim 1 further comprising:
a scintillator configured to convert extreme ultraviolet (EUV) light included in the second optical output to visible light; and
an optic configured to generate a third optical output having third magnification parameters.

9. The system of claim 1, wherein the optical input is received based on light from the light source reflecting off of a lithography target.

10. The system of claim 1, wherein the light source is an EUV light source.

11. A device comprising:
a first diffractive optic configured to receive an optical input based on light generated by a light source, and further configured to generate a first optical output having first magnification parameters along a first direction of an optical plane; and
a second diffractive optic configured to receive the first optical output, and further configured to generate a second optical output having second magnification parameters along a second direction of the optical plane,
wherein the first direction is different than the second direction, and wherein the second optical output has a uniform depth of focus along the first direction and the second direction associated with an imaging plane.

12. The device of claim 11, wherein the first diffractive optic comprises a first cylindrical zone plate, and wherein the second diffractive optic comprises a second cylindrical zone plate.

13. The device of claim 12, wherein the first diffractive optic and the second diffractive optic are configured to be adjustably positioned along an optical axis.

14. The device of claim 11, wherein the first direction is orthogonal to the second direction.

15. The device of claim 11 further comprising:
a third diffractive optic configured to generate a third optical output having third magnification parameters.

16. The device of claim 15, wherein the third diffractive optic is a zone plate lens configured to provide magnification in both the first direction and the second direction.

17. The device of claim 11 further comprising:
one or more mirrors configured to configured to generate a third optical output having third magnification parameters.

18. The device of claim 11 further comprising:
a scintillator configured to convert extreme ultraviolet light included in the second optical output to visible light; and
an optic configured to generate a third optical output having third magnification parameters.

19. A method comprising:
receiving an optical input based on light generated by a light source;
generating, using a first diffractive optic, a first optical output having first magnification parameters along a first direction of an optical plane; and
generating, using a second diffractive optic, a second optical output having second magnification parameters along a second direction of the optical plane,
wherein the first direction is different than the second direction, and wherein the second optical output has a uniform depth of focus along the first direction and the second direction associated with an imaging plane.

20. The method of claim 19, wherein the first diffractive optic comprises a first cylindrical zone plate, and wherein the second diffractive optic comprises a second cylindrical zone plate.

21. The method of claim 19 further comprising:
generating, using a third diffractive optic, a third optical output having third magnification parameters, wherein the third diffractive optic is positioned after an intermediate image generated by the second diffractive optic.

22. The method of claim 21, wherein the third diffractive optic is a zone plate lens configured to provide magnification in both the first direction and the second direction.

23. The method of claim 19 further comprising:
generating, using a mirror, a third optical output having third magnification parameters.

24. The method of claim 19 further comprising:
converting, using a scintillator, extreme ultraviolet (EUV) light included in the second optical output to visible light; and
generating, using an optic, a third optical output having third magnification parameters.
